(19) United States
(12) Patent Application Publication
(10) Pub. No.: US 2018/0047998 A1
(43) Pub. Date: Feb. 15, 2018

(54) METAL STRIP OR SHEET HAVING A CHROMIUM-NITRIDE COATING, BIPOLAR PLATE AND ASSOCIATED MANUFACTURING METHOD

(71) Applicant: APERAM, Luxembourg (LU)

(72) Inventors: Pauline GIRARDON, LOOS (FR); Sébastien TAHON, MAMETZ (FR); Jean-Michel DAMASSE, LOMME (FR); Marie-Hélène BERGER, VIRY-CHATILLON (FR); Hughes CORNIL, MARCHIN (BE); Olivier HENROTTE, Ouffet (BE); Alain PIMARD, Pont de Roide (FR)

(73) Assignee: APERAM, Luxembourg (LU)

(21) Appl. No.: 15/559,746

(22) PCT Filed: Mar. 20, 2015
(86) PCT No.: PCT/IB2015/052062

§ 371 Date: Sep. 19, 2017

(51) Int. Cl. H01M 8/0228; C30B 23/02; C23C 14/06; H01M 8/0215; C23C 14/00; C30B 29/38; H01M 8/021

(52) U.S. Cl. CPC H01M 8/0228; C30B 29/38; C30B 23/025; H01M 8/021; H01M 8/0215; C23C 14/0036; C23C 14/0641

(57) ABSTRACT

The present invention relates to a metal strip or sheet comprising a substrate made from stainless steel covered with at least one layer of a chromium-nitride coating. The chromium-nitride coating layer is textured.

### CROSS-REFERENCE TO RELATED APPLICATIONS

This is a U.S. national phase application under 35 U.S.C. § 371 of International Patent Application No. PCT/IB2015/052062, filed Mar. 20, 2015. The entire content of this application is hereby incorporated by reference.

### FIELD OF TECHNOLOGY

The present invention relates to a metal strip or sheet comprising a substrate made from stainless steel covered with at least one layer of a chromium-nitride based coating.

Proton exchange membrane fuel cells (PEMFC) comprise cell units each made up of an anode/electrolyte/cathode assembly, also called membrane electrode assembly (MEA), gas diffusion layers (GDL), extending on either side of the MEA assembly, and bipolar plates. The bipolar plates ensure the assembly of the elements of the cell unit to one another. They further define fluid circulation channels, ensuring the distribution of the gases, cooling liquid and discharge of the water generated in the cell. They also serve to collect the current generated at the electrodes.

### BACKGROUND

In light of the essential role played by the bipolar plates within the fuel cell, as well as the growing importance of such cells in many fields, it is desirable to develop compact bipolar plates that are inexpensive to manufacture and further have a long lifetime during operation in the fuel cell.

### SUMMARY

One aim of the invention is therefore to provide bipolar plates that are inexpensive to manufacture and further have a long lifetime during operation in the fuel cell.

To that end, the invention relates to a metal strip or sheet as described above, wherein the chromium-nitride based coating layer is textured.

According to specific features, the metal strip or sheet has one or more of the following features, considered alone or according to any technically possible combination(s):

the coating layer has an epitaxial relationship with the substrate;

the chromium-nitride based coating layer is obtained using a physical vapor deposition method, in particular by cathode sputtering;

the chromium-nitride based coating layer is formed directly on the stainless steel substrate, without interposition of a passive layer;

the substrate has a thickness comprised between 75 micrometers and 200 micrometers, and in particular a thickness smaller than or equal to 100 micrometers;

the grains of the substrate have a size strictly smaller than 50 micrometers, and in particular comprised between 10 micrometers and 30 micrometers;

the coating layer has a columnar structure, the width of the columns preferably being comprised between 10% and 20% of the thickness of the coating layer;

the coating layer optionally comprises oxygen, said coating layer being obtained by physical vapor deposition (PVD) and having, on its surface, a surface zone comprising an atomic oxygen content strictly lower than its atomic nitrogen content;

the surface zone has a height smaller than or equal to 15% of the total thickness of the coating layer;

the coating layer comprises, at the interface with the substrate, an interface zone comprising an atomic oxygen content strictly lower than its atomic nitrogen content;

the interface zone has a height less than or equal to 15% of the total thickness of the coating layer;

the metal strip or sheet consists, starting from the substrate and moving toward the surface of the coating layer, of the interface zone, a core zone and the surface zone, said zones being superimposed along a direction normal to the mean plane of the substrate.

The invention also relates to a plate obtained by deforming a strip or sheet as previously defined.

The invention also relates to a bipolar plate for a fuel cell comprising at least one plate as previously defined.

The invention also relates to a method for manufacturing a metal strip or sheet, which comprises the following steps:

providing a stainless steel substrate comprising, on its surface, a passive layer formed by natural oxidation of the stainless steel of the substrate;

completely stripping the passive layer in at least certain areas of the substrate;

depositing chromium nitride on the areas of the substrate in which the passive layer has been stripped so as to form a chromium-nitride based coating layer directly on the stainless steel substrate, without interposition of a passive layer, the coating layer thus formed being textured.

According to specific features of the method:

the coating layer thus formed has an epitaxial relationship with the substrate;

the stripping is a physical stripping;

the chromium-nitride based coating layer is deposited using a physical vapor deposition method, in particular by cathode sputtering;

the chromium nitride is deposited on the substrate in a deposition installation comprising a deposition chamber and a chromium target arranged in the deposition chamber, the substrate passing through the deposition chamber in a longitudinal direction, the deposition chamber comprising a deposition area with a length strictly smaller than the length of the deposition chamber, considered along the longitudinal direction, and at least a first prohibited area, adjacent to the deposition area in the longitudinal direction, and during the deposition, the chromium nitride is deposited on the substrate only in the deposition area and no chromium nitride is deposited on the substrate in the first prohibited area.

### BRIEF DESCRIPTIONS OF THE DRAWINGS

The invention will be better understood upon reading the following description, provided solely as an example and done in reference to the appended drawings, in which:

FIG. 1 is a schematic view of a metal strip according to the invention;

FIG. 2 is a schematic illustration of a method for manufacturing the strip of FIG. 1;

FIG. 3 is a schematic illustration of a deposition installation;

FIG. 4 is a schematic illustration of a bipolar plate according to the invention;

FIG. 5 is an image obtained by processing a transmission electron microscopy image of a blank from the strip of FIG. 1;

FIG. 6 is an image similar to that of FIG. 5, used as a comparison on a strip that is not according to the invention;

FIG. 7 is a scanning electron microscopy image of a plate obtained by stamping a blank obtained from the strip of FIG. 1;

FIG. 8 is an image similar to that of FIG. 7 of a plate obtained by stamping a blank obtained from a strip that is not according to the invention;

FIG. 9 is a transmission electron microscopy image of a plate obtained by stamping a blank obtained from the strip of FIG. 1;

FIG. 10 is an image similar to that of FIG. 9 obtained from a plate obtained by stamping a blank obtained from a strip that is not according to the invention;

FIG. 11 is a schematic view of a metal strip according to another example of the invention;

FIG. 12 is a schematic illustration of part of a method for manufacturing the strip of FIG. 11;

FIG. 13 is a schematic illustration of a deposition installation according to a further example;

FIG. 14 is a schematic illustration of a deposition installation that is not according to the invention;

FIG. 15 is a schematic illustration of a deposition installation according to a yet further example; and

FIG. 16 is a schematic illustration of the assembly for measuring the contact resistance.

### DETAILED DESCRIPTION

Throughout the description, the expression “comprised between a and b” must be understood as including the boundaries a and b.

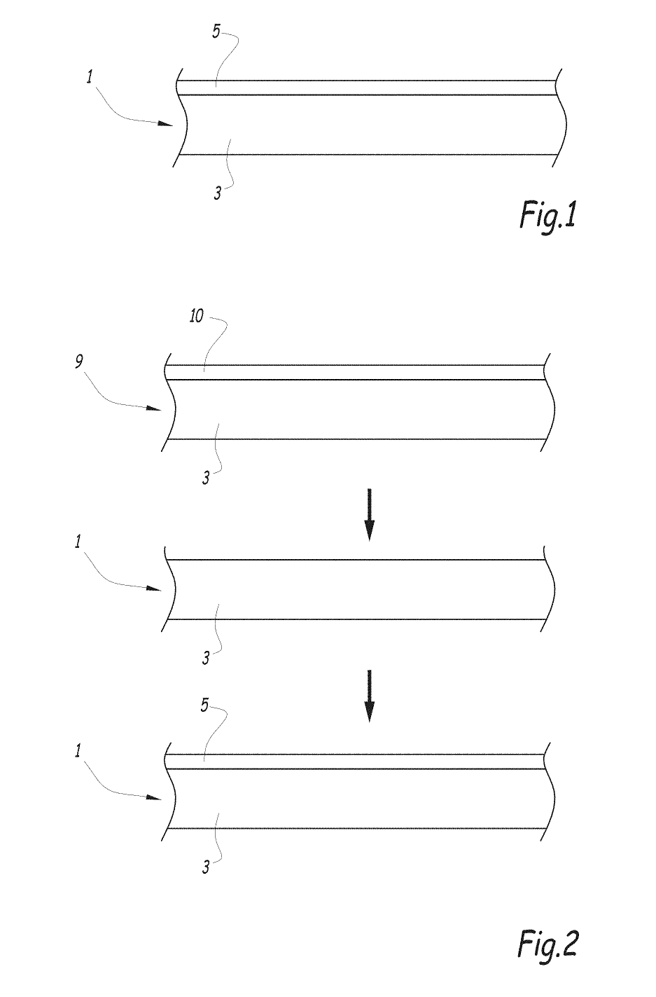

The metal strip 1 illustrated in FIG. 1 comprises a stainless steel substrate 3 and at least one coating layer 5.

More particularly, the substrate 3 is a strip made from stainless steel, and in particular ferritic or austenitic stainless steel. As an example, the substrate 3 is made from 1.4404, 1.4306, 1.4510 or 1.4509 stainless steel.

The substrate 3 has a thickness comprised between 75 micrometers and 200 micrometers, and in particular a thickness smaller than or equal to 100 micrometers.

The substrate 3 in strip form is obtained using any appropriate conventional methods, for example by hot rolling in one or several passes, followed by cold rolling in one or several passes, of a slab made from the desired alloy, the method being able to comprise one or several heat treatments, in particular for annealing.

The stainless steel of the substrate 3 is polycrystalline. It is therefore made up of multiple grains. The grains of the steel forming the substrate 3 have a size strictly smaller than 50 micrometers, and in particular comprised between 10 micrometers and 30 micrometers.

The coating layer 5 is a layer based on chromium-nitride of type CrN.

As will be seen later, the chromium-nitride based layer optionally comprises oxygen within the limits that will be specified later.

As an example, the chromium-nitride based coating layer 5 consists of CrNₓO_{y}, with x comprised between 0.6 and 2 and y strictly below 1.4 and possible impurities, in particular impurities resulting from manufacturing.

The sum of x and y is such that the chromium-nitride based coating layer 5 has the face-centered cubic crystallographic structure of the Cr₁N₁. This crystallographic structure is known by those skilled in the art.

The coating layer 5 for example has a thickness comprised between 3 nm and 150 nm. It is more particularly greater than or equal to 50 nm, and for example greater than or equal to 50 nm and less than or equal to 100 nm.

The coating layer 5 is obtained using a physical vapor deposition method.

The use of the physical vapor deposition method to deposit the chromium-nitride based coating layer 5 results in a distinctive microstructure of this coating layer. In particular, the coating layer 5 has a columnar structure, with grains having a size substantially identical, if not comparable, to that of the steel making up the substrate 3.

The coating layer 5 has a growth direction normal to the substrate 3.

The use of the physical vapor deposition method results in a columnar structure of the coating layer 5, made up of columns with a width comprised between 10% and 20% of the thickness of the coating layer 5. As an example, the width of the columns is about 10 nanometers.

The columns of the coating layer 5 grow along the growth direction of the coating layer 5. In this context, the column length refers to the dimension of the column in a direction normal to the substrate 3, and the width refers to the dimension of a column in a plane parallel to the mean plane of the substrate 3.

The coating layer 5 of the metal strip 1 is textured from a crystallographic perspective. This texturing results in the implementation of the method that will be described later.

“Textured” means that the crystallographic growth directions of the columns making up the coating layer 5 are not random, but highly oriented along one of the crystallographic axes defining the elementary mesh of the CrN. In this case, the relative orientation of the elementary meshes of the coating layer 5 and the substrate 3 makes it possible to align the crystallographic planes of the two phases having close inter-reticular distances and to ensure the continuity of these crystallographic planes perpendicular to the interface between the substrate 3 and the coating layer 5.

Preferably, the coating layer 5 has an epitaxial relationship with the substrate 3. “Epitaxial” means, conventionally, that the three crystallographic axes of the columns of the coating layer 5 are aligned with those of the grains of the substrate 3 adjacent to these columns.

As will be seen later, a coating layer 5 having an epitaxial relationship with the substrate 3 is particularly advantageous.

The metal strip 1 advantageously consists of the substrate 3 and one or several chromium-nitride based coating layers 5. In particular, the chromium-nitride based coating layer 5 is formed directly on the stainless steel of the substrate 3, without interposition of an intermediate layer, such as a passive or oxidation layer, resulting from the natural oxidation of the stainless steel making up the substrate 3. Natural oxidation refers to oxidation in the air, for example during the use or storage of the stainless steel substrate 3.

Furthermore, preferably, the metal strip 1 does not comprise layers formed above the coating layer 5 furthest from the substrate 3.

A method for obtaining a metal strip 1 according to the invention will now be explained in reference to FIG. 2.

In a first step, a metal strip 9 is provided comprising a substrate 3 made from stainless steel covered, on its surface, with a passive chromium-oxide layer 10 formed by natural oxidation of the stainless steel making up the substrate 3. Such a passive chromium-oxide layer forms on the surface of the stainless steel once the latter comes into contact with the air. It is at the base of the stainless nature of the stainless steel. The passive layer 10 may traditionally comprise, aside from the chromium oxide, and as a minority component, oxides of other chemical elements present in the steel forming the substrate 3.

In a second step, the passive layer 10 is completely stripped in at least certain areas of the metal strip 9 such that, in these areas, no remnants of passive layer 10 remain.

Preferably, during the second step, the passive layer 10 is stripped over the entire surface of the substrate 3 intended to be coated with the coating layer 5.

The stripping is done using a physical stripping method. Preferably, the stripping is an ion stripping, done by bombardment of the initial metal strip by a neutral gas. The natural gas used is for example argon. Alternatively, it may be any other suitable neutral gas.

Such an ion stripping method is known as such and will not be described in more detail below.

At the end of this stripping, the substrate 3 is obtained having the metal atoms of the stainless steel on its surface in the areas in which the stripping has been done.

During a third step, physical vapor deposition (PVD) is done using a physical vapor deposition installation 14, for depositing chromium nitride on the substrate 3 in the areas in which the passive layer 10 has been stripped.

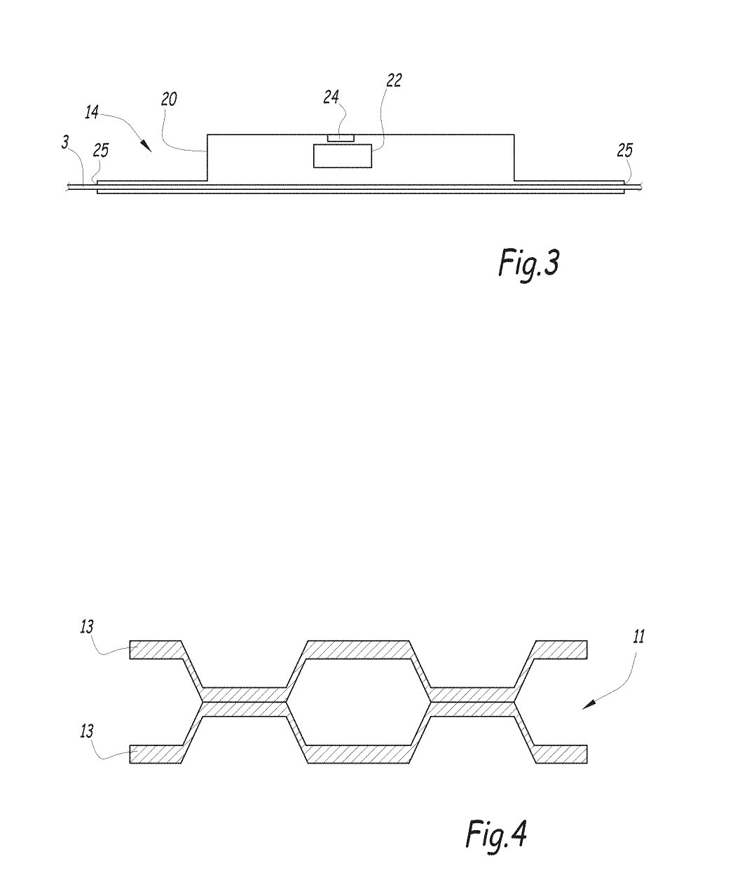

Conventionally, the physical vapor deposition installation 14, shown in FIG. 3, comprises a deposition chamber 20, able to be placed under vacuum, and a target 22. The target 22 is made from chromium.

The substrate 3 passes through the chamber 20 along a travel direction, called longitudinal direction hereinafter. In the entire description, the terms upstream and downstream are used in reference to the travel of the substrate 3 through the chamber 20.

The chamber 20 comprises, at each of its longitudinal ends, a passage opening 25 for the substrate 3. The openings 25 are advantageously sealed.

In the illustrated example, the chamber 20 comprises an inert gas source 24. This inert gas is for example argon.

The PVD method used is advantageously a cathode sputtering method. In this case, the target 22 is called “cathode sputtering target”. The chamber 20 comprises means for applying a difference in potential between the target 22 and the substrate 3, such that the target 22 forms the cathode of the deposition installation 14 and the substrate 3 forms the anode of the deposition installation 14.

The deposition of the coating layer 5 on the substrate 3 is done by bombarding the target 22 using the inert gas from the inert gas source 24 in an atmosphere also comprising nitrogen.

More specifically, and as illustrated in FIG. 3, during the deposition step, the substrate 3 in strip form travels through the chamber 20.

An appropriate difference in potential is applied between the target 22 and the substrate 3.

The inert gas projected, in plasma form, on the target 22, extracts chromium atoms therefrom, which subsequently condense on the substrate 3 so as to form the chromium-nitride based coating layer 5, the chromium being combined with the nitrogen present in the chamber 20.

The deposition is done on a substrate 3 at ambient temperature, for example about 20° C.

During this deposition step, the nitrogen flow rate injected into the chamber 20 is adjusted in order to obtain the desired stoichiometry of the nitrogen in the chromium-nitride based coating layer 5. The stability of the deposition stoichiometry is ensured by the analysis of the light spectrum emitted by the plasma during deposition of the coating by PVD. Indeed, analyzing this spectrum makes it possible to deduce the relative concentrations of chromium and nitrogen present in the plasma.

The specific flow rates of nitrogen to be used as a function of the stoichiometry vary as a function of the PVD installation used. However, one skilled in the art is capable, using his general knowledge and through a limited number of calibration tests linking the light spectrum emitted by the plasma and stoichiometry measurements of the coating layers obtained for different nitrogen flow rates, to determine the nitrogen flow rate to be used, for a given installation, based on the desired stoichiometry in the coating layer 5.

The chromium-nitride based coating layer 5 is thus formed directly on the stainless steel substrate 3, without interposition of a passive layer. The coating layer 5 obtained at the end of this step is textured. More particularly, it has an epitaxial relationship with the substrate 3.

At the end of the third step, the metal strip 1 according to the invention is thus obtained.

The invention also relates to a bipolar plate 11 obtained from the metal strip 1. Such a bipolar plate 11 is shown in FIG. 4.

As shown in FIG. 4, the bipolar plate 11 comprises two plates 13 secured to one another, in particular by welding. More particularly, the plates 13 define, after they are secured, fluid distribution and discharge channels.

Each plate 13 is obtained from a metal strip 1 according to the invention. More particularly, it is obtained by deformation, in particular cold, of a blank cut from the metal strip 1.

Each plate 13 thus comprises a stainless steel substrate 3, coated with at least one chromium-nitride based coating layer 5, as previously described in connection with the metal strip 1.

The final shape of the plates 13 is advantageously obtained by cold stamping a blank cut from the metal strip 1.

The invention also relates to a method for producing a bipolar plate 11 from a metal strip 1 comprising:

providing a plate 13 comprising a stainless steel substrate 3, coated with at least one chromium-nitride based coating layer 5, as previously described; and

securing this plate 13 to another plate, and advantageously to another similar plate 13, so as to form the bipolar plate 11.

The step for providing the plate 13 comprises:

cutting the metal strip 1 to form at least one blank; and

deforming this blank, in particular by stamping, to form a plate 13.

As previously explained, the deformation is advantageously a cold deformation, and in particular cold stamping.

The securing of the two plates to one another to form the bipolar plate 11 is done using any appropriate method, and in particular by welding.

The inventors of the present invention carried out the following experiments.

They implemented, on a metal strip 9 as previously defined, the method for upon manufacturing a metal strip 1 as shown in FIG. 1, and thus obtained a metal strip 1.

They next cut blanks from this metal strip 1. They imaged these blanks using transmission electron microscopy (TEM) and analyzed the images thus obtained through known image analysis techniques to verify whether an epitaxial relationship existed between the substrate 3 and the coating layer 5.

More particularly, they calculated the Fourier transforms of the images obtained by TEM, the Fourier transforms making it possible to explore the frequency distributions of the images obtained by TEM. In the Fourier transforms images, they selected the frequencies corresponding to the crystallographic planes of the substrate 3 and the coating layer 5 for which a close orientation is observed in the space of the frequencies. They next obtained the final images by inverse Fourier transform filtered from the selected frequencies.

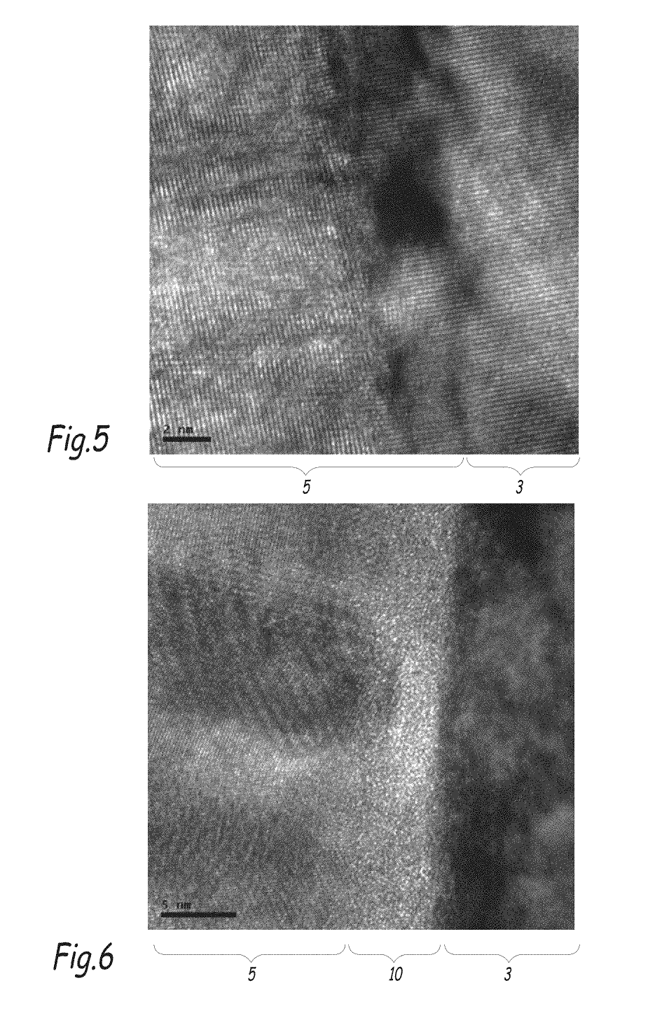

An example image obtained after analysis is shown in FIG. 5. In this figure, the diagonal lines depict the atomic planes. The continuity of the lines upon passing the interface between the substrate 3 and the coating layer 5 shows that the coating layer 5 has an epitaxial relationship with the substrate 3.

The inventors performed such analyses for metal strips 1 obtained with different nitrogen flow rates during the step for deposition of the coating layer 5. They observed that the epitaxial relationship between the substrate 3 and the coating layer 5 exists irrespective of the nitrogen flow rate used.

For comparison, the inventors conducted experiments with metal strips obtained using a method different from the method according to the invention only in that during the second step, the passive layer 10 was not completely stripped in the areas of the substrate 3 coated with the coating layer 5. Thus, this passive layer 10 remains in areas next coated with the chromium-nitride based coating layer 5, and is interposed between the coating layer 5 and the substrate 3.

FIG. 6 shows an example image obtained after analysis of the TEM image of such a strip, which is not according to the invention, using the analysis method explained above. In this case, one can see that there is no continuity of the atomic planes at the interface between the substrate 3 and the coating layer 5. In this image, the white area between the substrate 3 and the coating layer 5 corresponds to the passive layer 10.

Thus, the inventors have observed that the epitaxial relationship between the coating layer 5 and the substrate 3 is not obtained when the passive layer 10 has not been stripped, or has not been completely stripped before coating in the areas of the substrate 3 intended to be covered with the coating layer 5.

The inventors next deformed blanks, by stamping, obtained by cutting a metal strip 1 according to the invention in order to obtain plates 13.

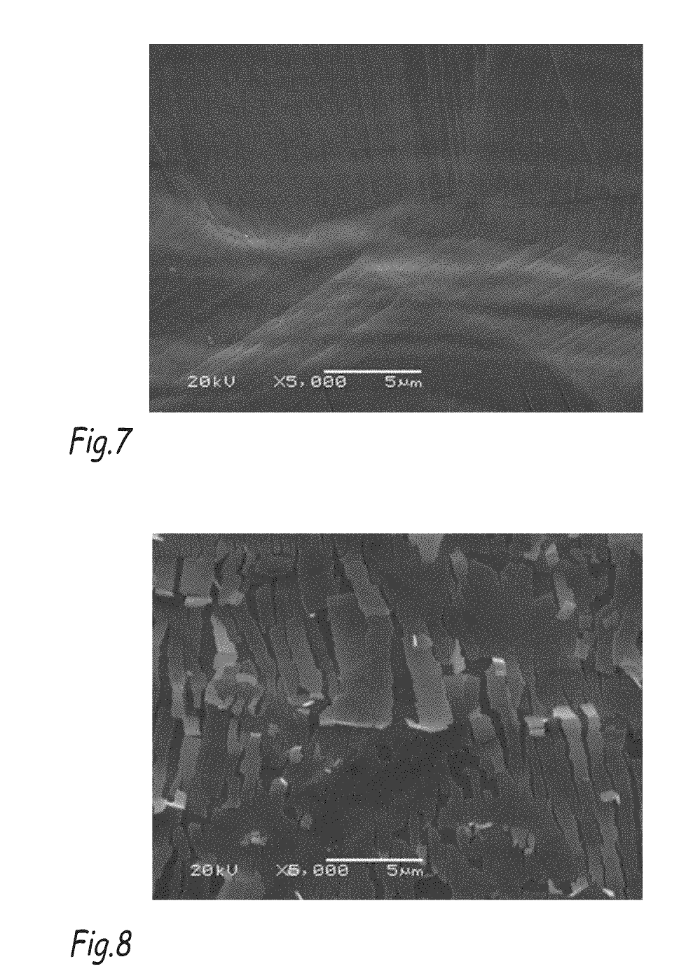

FIG. 7 is a scanning electron microscopy image of a plate 13 thus obtained. In this image, no unsticking is observed between the coating layer 5 and the substrate 3 resulting from the stamping. Thus, the coating layer 5 has a satisfactory adherence on the substrate 3. Yet a good adherence of the coating layer 5 is particularly advantageous during the use of the strip 1 in a bipolar plate. Indeed, it makes it possible to guarantee the bipolar plate good electrical properties, in particular electrical conductivity, and avoids electrolyte poisoning.

FIG. 8 is a scanning electron microscopy image of a plate obtained by stamping blanks obtained by cutting from the strip that is not according to the invention described above. In this image, unsticking of the coating layer 5 is observed. Thus, the adherence of the coating layer 5 is, in this case, insufficient to withstand the deformation by stamping of the blank.

It will be noted that, in the context of the invention, the deformation by stamping of the blank obtained from this metal strip 1 to form a plate 13 can result in a plate 13 having a discontinuous coating layer 5.

Indeed, due to the different mechanical properties of the substrate 3 and the coating layer 5, the stamping results in a much higher relative elongation of the substrate 3 with respect to the coating layer 5. Due to the good adherence between the substrate 3 and the coating layer 5 according to the invention, this differential elongation results in the formation of microcracks 26 in the coating layer 5 of the plate 13, and therefore in the formation of a discontinuous coating layer on the plate 13. These microcracks 26 in particular form between two adjacent columns of the coating layer 5. The passive layer naturally reforms in these microcracks 26 by natural oxidation of the stainless steel of the substrate 3, which is flush in these areas.

The inventors have observed that, even in the presence of microcracks 26, no loss of coating occurs during the stamping of blanks obtained from strips 1 according to the invention.

Furthermore, owing to the good adherence between the coating layer 5 and the substrate 3, the coating layer 5 does not unstick from the substrate 3 during stamping, and one observes, in the plate 13, very good adherence between the discontinuous coating layer 5 and the substrate 3.

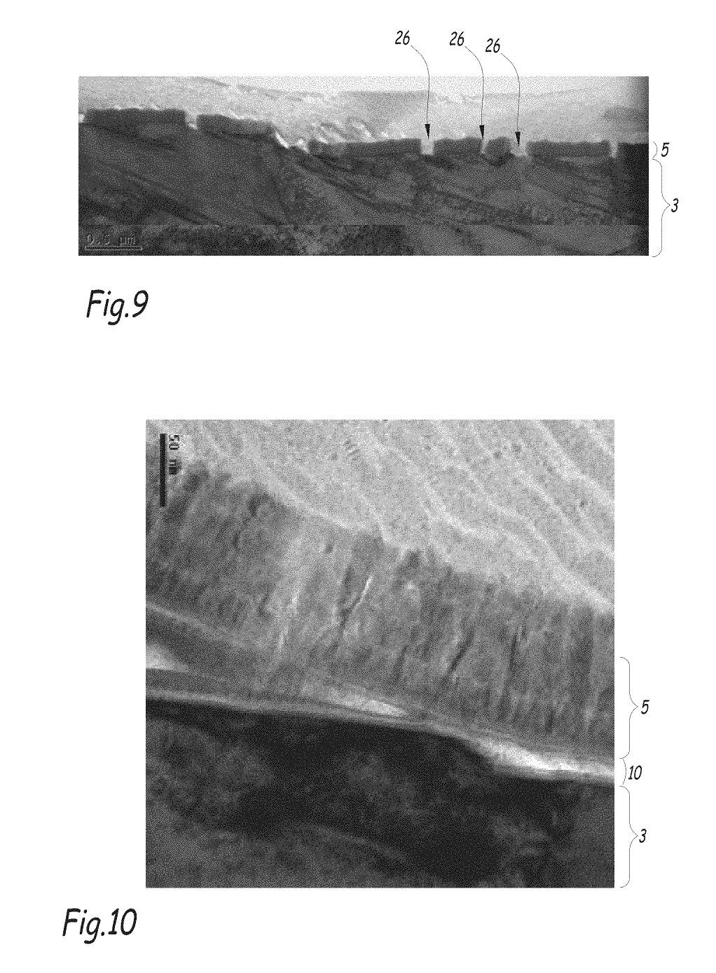

FIG. 9, which is a transmission electron microscopy image of a plate 13 according to the invention, illustrates these observations.

The inventors measured the electrical conductivity of such a discontinuous layer and observed that the electrical performance remained satisfactory, despite the presence of the microcracks 26. The passive layer that reforms after stamping between the adjacent columns of the coating layer 5 is not detrimental to the electrical conductivity and protects the stainless steel of the substrate 3 in the areas where it is flush.

FIG. 10 is a scanning electron microscopy image of a plate obtained by stamping from the strip that is not according to the invention described above. In this case, one can see that the coating layer 5 has unstuck from the substrate 3 and slid by one piece in response to the elongation of the substrate 3 under the effect of the stamping. In the plate thus obtained, the coating layer 5 therefore no longer adheres to the substrate 3. Yet one seeks to avoid such unsticking, which is detrimental to the electrical conductivity of the bipolar plate and risks leading to electrolyte poisoning of the fuel cell.

The metal strip 1 according to the invention is particularly suitable for manufacturing bipolar plates having a long lifetime for lower manufacturing costs.

Indeed, stainless steel is an inexpensive material that furthermore has very advantageous properties for use as a bipolar plate. In particular, it has excellent mechanical properties. It is also able to be stamped, welded, is impermeable to gases, and has a high electrical conductivity in its thickness, as well as a good thermal conductivity.

However, when a bare stainless steel substrate is used in bipolar plates of fuel cells, these bipolar plates have insufficient electrical properties. The chromium-nitride based textured coating layer according to the invention imparts good electrical conduction properties to the bipolar plate, in particular resulting from the excellent adhesion of the coating layer to the substrate 3.

According to one alternative, the invention relates to a metal sheet or blank obtained by cutting the metal strip 1.

The metal sheet according to the invention can also be obtained using a method similar to that previously described to obtain the strip 1, but starting from a metal sheet during the first step of the method, rather than a strip.

Such a sheet has properties identical to those of the strip 1.

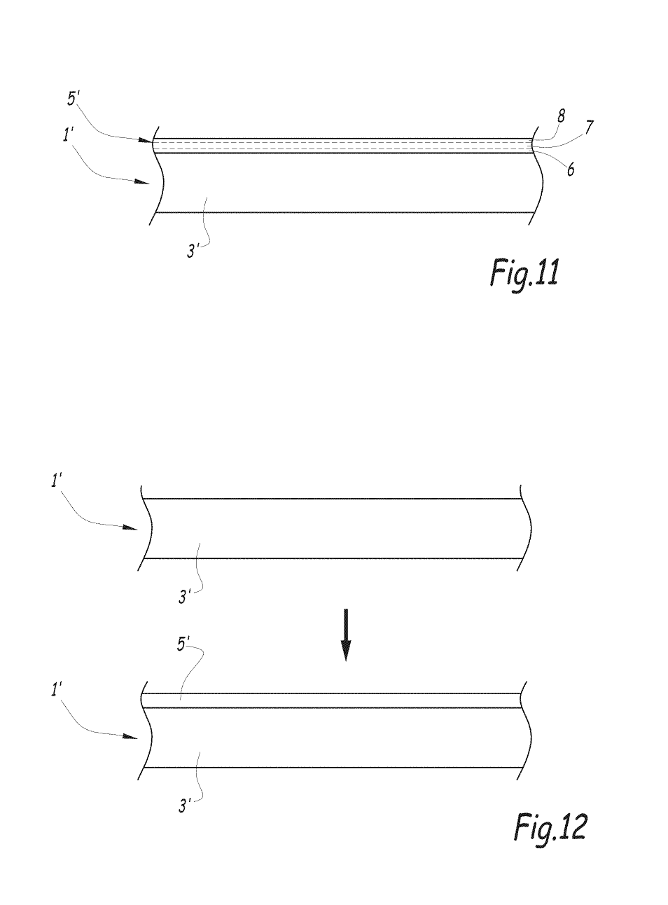

A metal strip 1′ according to another example of the invention will now be described in light of FIG. 11. This strip 1′ has all of the characteristics of the strip 1, and in particular its texturing properties, but further has the specific characteristics described below.

As illustrated in FIG. 11, the coating layer 5′ of the strip 1′ is made up of three superimposed zones along the direction of the coating layer 5′, i.e., along the direction normal to the mean plane of the substrate 3′. Each zone extends over the entire surface of the coating layer 5′, considered parallel to the mean plane of the substrate 3′. Preferably, each zone has a substantially constant thickness.

More particularly, the coating layer 5′ consists, starting from the substrate 3′ and moving toward the surface of the coating layer 5′, in the direction normal to the mean plane of the substrate 3′, of an interface zone 6, a core zone 7 and the surface zone 8.

The surface zone 8 of the coating layer 5′ is located at the surface of the coating layer 5′.

The surface zone 8 has an atomic oxygen content strictly lower than its atomic nitrogen content. It will be considered that the difference between the ratio of the atomic oxygen content to the atomic chromium content and the ratio of the atomic nitrogen content to the atomic chromium content in the surface zone 8 is preferably greater than or equal to 0.1.

The surface zone 8 has a composition of the type: CrNₓ₁O_{y1}, with y1 strictly less than x1, the rest consisting of possible impurities, in particular impurities resulting from manufacturing. These impurities do not include oxygen. The difference between x1 and y1 is preferably at least equal to 0.1.

The coefficient x1 corresponds to the ratio of the atomic nitrogen content to the atomic chromium content in the surface zone 8. The coefficient y1 corresponds to the ratio of the atomic oxygen content to the atomic chromium content in the surface zone 8.

The sum of the coefficients x1 and y1 is such that the surface zone 8 has the face-centered cubic crystallographic structure of the Cr₁N₁.

x1 is advantageously comprised between 0.6 and 2.

Independently of the value of x1, y1 is advantageously less than or equal to 1.4, while being strictly less than x1, and while being such that the surface zone 8 retains the crystallographic structure of the Cr₁N₁.

In particular, the surface zone 8 extends over at least 5% of the thickness of the coating layer 5′. It extends at most over about 15% of the thickness of the coating layer 5′.

No oxidation layer, which would result from the oxidation of the coating layer 5′, is formed on the surface zone 8.

The interface zone 6 of the coating layer 5′ is located at the interface with the substrate 3′. It is in direct contact with the steel making up the substrate 3′. It forms the part of the coating layer 5′ closest to the substrate 3′.

Advantageously, the interface zone 6 has an atomic oxygen content strictly lower than its atomic nitrogen content. The difference between the ratio of the atomic oxygen content to the atomic chromium content and the ratio of the atomic nitrogen content to the atomic chromium content in the interface zone 6 is preferably greater than or equal to 0.1.

The interface zone 6 has a composition of the type: CrNₓ₂O_{y2}, with y2 strictly less than xx, the rest consisting of possible, in particular impurities resulting from manufacturing. These impurities do not include oxygen. The difference between x2 and y2 is preferably at least equal to 0.1.

The coefficient x2 corresponds to the ratio of the atomic nitrogen content to the atomic chromium content in the interface zone 6. The coefficient y2 corresponds to the ratio of the atomic oxygen content to the atomic chromium content in the interface zone 6.

The sum of the coefficients x2 and y2 is such that the interface zone 6 has the face-centered cubic crystallographic structure of the Cr₁N₁.

x2 is advantageously comprised between 0.6 and 2.

Independently of the value of x2, y2 is advantageously less than or equal to 1.4, while being strictly less than x1, and while being such that the interface zone 6 retains the crystallographic structure of the Cr₁N₁.

In particular, the interface zone 6 extends over at least 1% of the thickness of the coating layer 5′. It extends at most over about 15% of the thickness of the coating layer 5′. More particularly, it extends at most over 10% of the thickness of the coating layer 5′.

The core zone 7 of the coating layer 5′ forms the core of the coating layer 5′. It extends, along the direction normal to the mean plane of the substrate 3′, between the interface zone 6 and the surface zone 8. It makes up the majority of the thickness of the coating layer 5′. Advantageously, it extends over at least 70% of the thickness of the coating layer 5′.

In particular, the core zone 7 has an atomic oxygen content strictly lower than a third of its atomic nitrogen content. In other words, it has a composition of the type: CrNₓ₃O_{y3}, with y3 strictly less than

$$\frac{x 3}{3} ,$$

the rest consisting of possible impurities, in particular impurities resulting from manufacturing. These impurities do not include oxygen.

The coefficient x3 corresponds to the ratio of the atomic nitrogen content to the atomic chromium content in the core zone 7. The coefficient y3 corresponds to the ratio of the atomic oxygen content to the atomic chromium content in the core zone 7.

The sum of the coefficients x3 and y3 is such that the core zone 7 has the face-centered cubic crystallographic structure of the Cr₁N₁.

x3 is advantageously comprised between 0.6 and 2.

Independently of the value of x3, y3 is advantageously less than or equal to 1.4, while being strictly less than

$$\frac{x 3}{3} ,$$

and while being such that the core zone 7 retains the crystallographic structure of the Cr₁N₁.

A coating layer 5′ having a surface zone 8 as defined above, in which the atomic oxygen content is strictly less than the atomic nitrogen content, is particularly advantageous for use as a bipolar plate in fuel cells. Indeed, the inventors have noted that, when the atomic oxygen content in the surface zone 8 is strictly lower than the atomic nitrogen content, the interfacial contact resistance (ICR) measured between a sheet cut from such a strip and a gas diffusion layer with SGL Group reference 34BC is less than 10 mΩ·cm² at 100 N·cm⁻².

On the contrary, the inventors have noted that when the atomic oxygen content of the surface zone 8 is greater than or equal to its atomic nitrogen content, much higher contact resistances are measured, at least equal to 100 mΩ·cm² at 100 N·cm⁻², which is not completely satisfactory for use as a bipolar plate in a fuel cell.

Furthermore, the inventors have noted that when the coating layer 5′ comprises, in its interface zone 6, an atomic oxygen content strictly lower than its atomic nitrogen content, the coating layer 5′ has better adherence to the substrate 3′ that a coating layer in which this condition is not met. This property is particularly advantageous when the strip 1 is used to manufacture bipolar plates for fuel cells. Indeed, insufficient adherence of the coating layer 5′ on the substrate 3′ increases the risks of it unsticking during shaping, in particular by stamping, such unsticking risking deteriorating the electrical conduction properties of the bipolar plate.

Part of a method for manufacturing a metal strip 1′ comprising a coating layer 5′ is illustrated schematically in FIG. 12.

The first two steps of the method (providing the metal strip comprising the substrate 3′ and a passive layer and stripping the passive layer) are identical to those described previously in reference to the metal strip 1. In FIG. 12, these steps have not been shown, only the third step being illustrated.

The third step differs from the third step of the method previously described only by the characteristics mentioned below.

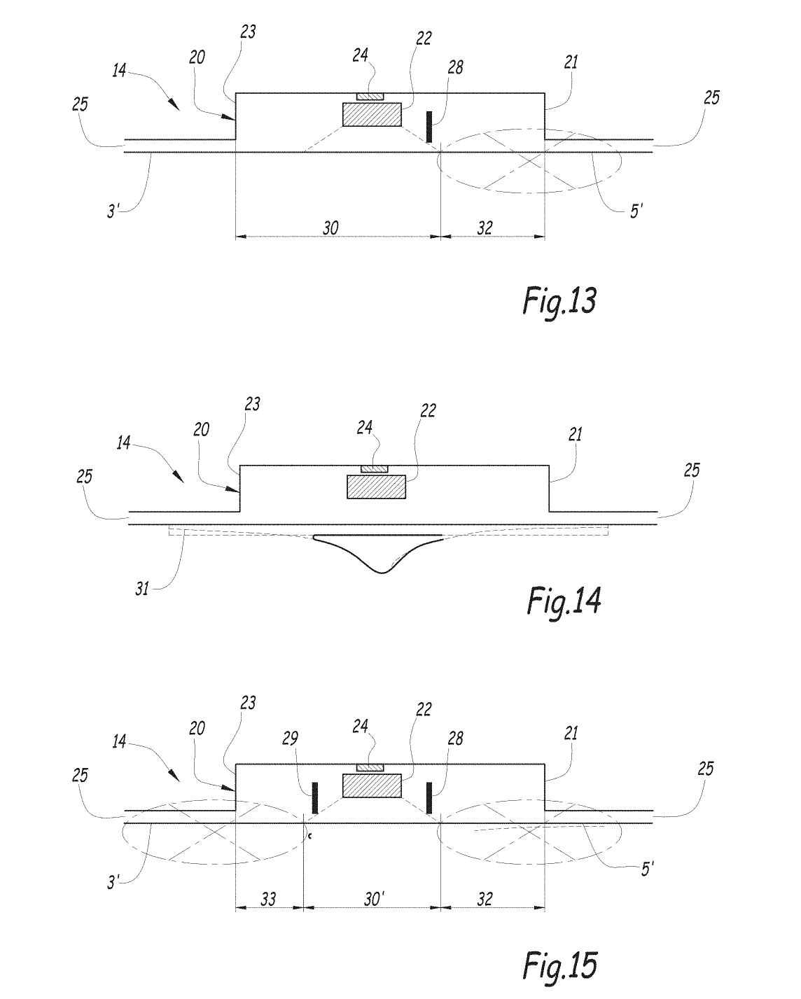

According to this example, and as illustrated in FIG. 13, the deposition chamber 20 comprises a deposition zone 30 and a first so-called “prohibited” area 32, adjacent to the deposition area 30 in the longitudinal direction. A prohibited area is defined as an area of the chamber 20 situated on the path of the substrate 3′ in which one does not wish for chromium coating to be produced.

The length of the deposition area 30 is strictly smaller than the length of the deposition chamber 20. More particularly, the deposition area 30 has a length strictly smaller than the length of the area of the chamber 20 in which chromium would be deposited on the substrate 3′ without the prohibited area 32.

The deposition area 30 and the first prohibited area 32 are therefore defined such that, during deposition, the chromium nitride is deposited on the substrate 3′ only in the deposition area 30 and the deposition of chromium nitride is prevented on the substrate 3′ in the first prohibited area 32.

The first prohibited area 32 is situated downstream from the target 22 on the path of the substrate 3′.

The deposition area 30 and the first prohibited area 32 are configured such that, in the entire part of the deposition area 30 located downstream from the target 22 on the path of the substrate 3′, the deposition speed of the chromium atoms on the substrate 3′ is greater than or equal to a predetermined threshold speed. The first prohibited area 32 corresponds to an area in which the chromium atoms from the target 22 would be deposited on the substrate 3′ at a speed strictly lower than the threshold speed if they were free to be deposited on their natural trajectory.

Indeed, the inventors have noted that the oxygen content of the coating is locally strictly higher than the desired content previously described in the coating zones formed by the deposition of chromium atoms at a speed strictly lower than the predetermined threshold speed.

The predetermined threshold speed is equal to a percentage of the maximum deposition speed of the chromium atoms on the substrate 3′. The deposition speed is maximal across from the target 22. It decreases moving away from the target 22, in the longitudinal direction, over the path of the substrate 3′.

The value of the predetermined threshold speed is obtained experimentally by one skilled in the art, for a given deposition installation, through a limited number of experiments. It corresponds to the minimal deposition speed of the chromium atoms on the substrate 3′ downstream from the target 22 for which a contact resistance of the obtained coating layer is measured lower than 10 mΩ·cm² at 100 N·cm⁻².

As an example, in the case of the apparatus used by the inventors of the present invention, the threshold speed is equal to about 10% of the maximum deposition speed.

In order to deposit the chromium nitride on the substrate 3′ only in the deposition area 30, the second step comprises placing at least one downstream cover 28 in the deposition chamber 20, said downstream cover 28 being intended to prevent chromium atoms from being projected on the substrate 3′ from the target 22 outside the deposition area 30.

The cover 28 prevents chromium atoms from being projected on the substrate 3′ in the first prohibited area 32, in which the deposition speed of the chromium atoms on the substrate 3′ would be strictly below the given threshold. The downstream cover 28 is positioned on the trajectory of the chromium atoms, which, without the downstream cover 28, would be deposited on the substrate 3′, downstream from the target 22 along the path of the substrate 3′, with a deposition speed strictly lower than the predetermined threshold speed, and thus prevents the deposition of these atoms on the substrate 3′.

The cover 28 is arranged between the target 22 and the substrate 3′. The cover 28 is arranged away from the downstream wall 21 of the chamber 20. The first prohibited area 32 extends downstream from the cover 28.

As an example, the cover 28 is formed by a plate impermeable to the chromium atoms coming from the target 22. It is arranged substantially normally to the substrate 3′ traveling through the chamber 20.

The inventors have discovered that the definition in the deposition chamber 20 of such a deposition area 30, associated with a first prohibited area 32, makes it possible to form, on the substrate 3′, a coating layer 5′ comprising a surface zone 8 as previously defined, having an atomic oxygen content strictly lower than its atomic nitrogen content.

It will be noted that any oxygen that may be present in the coating layer 5′ results from inevitable sealing imperfections of the chamber 20′ and the desorption from the walls of the chamber 20 or even from the substrate 3′.

According to an alternative example, the downstream boundary of the deposition area 30 is determined by measuring the atomic oxygen content profile in a chromium-nitride based coating layer formed in the deposition chamber in the absence of definition of a prohibited area, and deducing the area of the chamber 20 therefrom, in which the surface area of the coating layer has an atomic oxygen content strictly lower than its atomic nitrogen content.

One thus obtains a coating layer 5′ comprising a surface zone 8 as defined above, in which the atomic oxygen content is strictly lower than the atomic nitrogen content.

The location of the deposition area obtained according to this alternative is substantially identical to the location determined using the deposition speeds.

FIG. 14 illustrates a chamber that is not part of the invention, due to the absence of prohibited area, but that illustrates the need to provide such areas. In this figure, a curve 31 is shown, obtained by the inventors, showing the evolution of the atomic oxygen content in the chromium-nitride based coating layer obtained in such a chamber. On this curve, one can see that the atomic oxygen content in this coating layer, deposited under conditions identical to the conditions according to the invention, but without prohibited areas, is minimal in the parts of the coating layer 5′ deposited across from the target 22. This atomic oxygen content increases in the parts of the coating layer 5′ deposited toward the upstream and downstream ends of the chamber 20 along the travel direction of the substrate 3′, while being maximal near these ends.

Optionally, the second step of the method further comprises, before depositing the coating layer 5′, minimizing the degassing rate of the chamber 20 in order to minimize the quantity of residual gases in the chamber 20 as much as possible. This minimization is in particular done by pumping residual gases from the chamber 20.

The determination of the minimal and maximal presence of oxygen in the atmosphere of the chamber 20 may be done experimentally based on local implementation conditions of the invention.

“Degassing rate” refers to the flow rates of all of the gases that desorb from all of the surfaces of the chamber 20 and that are added to the controlled nitrogen flow rate. This degassing acts as a disruption or chemical pollution with respect to the PVD done in the deposition chamber 20.

The coating layer 5′ is advantageously done in a single coating pass, i.e., by a single passage in the deposition chamber 20.

At the end of the deposition step, one obtains a metal strip 1′ comprising a coating layer 5′ having a surface zone 8 as defined above.

The manufacturing method according to a yet further example differs from the method described above only in that, as shown in FIG. 15, the deposition area 30′ is limited, not only downstream from the target 22 as described above, but also upstream from the target 22 along the path of the substrate 3′. In this example, the deposition area 30′ is defined such that the deposition speed of the chromium atoms on the substrate 3′ is greater than or equal to the predetermined threshold speed previously described in the entire deposition area 30′.

In this example, the chamber 20 then comprises a second prohibited area 33, adjacent to the deposition area 30′ upstream from the target 22 along the path of the substrate 3. The first prohibited area 32 and the second prohibited area 33 frame the deposition area 30′ along the longitudinal direction. The first prohibited area 32 and the second prohibited area 33 are areas in which the chromium atoms would be deposited on the substrate 3′ at a speed strictly lower than the predetermined threshold speed if they were free to be deposited on their natural trajectory.

In order to deposit the chromium nitride on the substrate 3′ only in the deposition area 30, the second step comprises placing at least one downstream cover 28 as previously defined in the deposition chamber 20, and an upstream cover 29.

The downstream cover 28 and the upstream cover 29 are configured to prevent chromium atoms from being projected on the substrate 3′ from the target 22 outside the deposition area 30′, i.e., in areas of the chamber 20 in which the deposition speed of the chromium atoms on the substrate 3′ is strictly lower than the given threshold. They are arranged on the trajectory of the chromium atoms that would, without the covers 28, 29, be deposited on the substrate 3′ in the first prohibited area 32 or in the second prohibited area 33, respectively, and prevent chromium atoms from being deposited in these areas 32, 33.

The downstream cover 28 and the upstream cover 29 are arranged on either side of the target 22, along the travel direction of the substrate 3′.

In the illustrated example, the covers 28, 29 are equidistant from the target 22, and the deposition area 30′ is centered on the target 22. In this example, the deposition area 30′ extends across from the target 22, in a central region of the chamber 20.

As an example, the upstream cover 29 is formed by a plate impermeable to the chromium atoms coming from the target 22. It is arranged substantially normally to the substrate 3′ traveling through the chamber 20.

The upstream cover 29 is arranged away from the upstream wall 23 of the chamber 20.

As an example, in the installation used by the inventors, the covers 28, 29 were spaced apart by 90 cm.

The inventors of the present invention observed that defining the deposition area 30′ upstream from the target 22, in particular using the upstream cover 29, makes it possible to obtain a coating layer 5′ comprising, in its interface zone 6, an atomic oxygen content strictly lower than its atomic nitrogen content. As previously explained, such a coating layer 5′ has better adherence to the substrate 3′ than a layer in which this condition is not met.

Thus, when the deposition area 30′ is defined upstream and downstream from the target 22 in the manner specified above, one obtains, at the end of the deposition step, a coating layer 5′ comprising, on its surface, the surface zone 8 as previously defined and, at the interface between the substrate 3′ and the coating layer 5′, the interface zone 6 as previously defined.

Furthermore, the coating layer 5′ comprises, between the interface zone 6 and the surface zone 8, a core zone 7 as previously defined.

According to an alternative of the other example, the upstream and downstream boundaries of the deposition area 30′ are determined by measuring the atomic oxygen content profile in a chromium-nitride based coating layer formed on a substrate under conditions identical to the conditions according to the invention, but without defining prohibited areas of the chamber, and deducing the area of the chamber 20 therefrom in which the surface area and the interface zone of such a coating layer have an atomic oxygen content strictly lower than its atomic nitrogen content.

The location of the deposition area 30′ obtained according to this alternative is substantially identical to the location determined using the deposition speeds.

At the end of the deposition step, one obtains a metal strip 1′ according to the invention.

Plates 13, as well as a bipolar plate 11 having the coating 5′, can be obtained using a method identical to the method previously described for the metal strip 1, but applied to the metal strip 1′.

As previously explained, the metal strip 1′ according to the invention is particularly suitable for producing such bipolar plates 11.

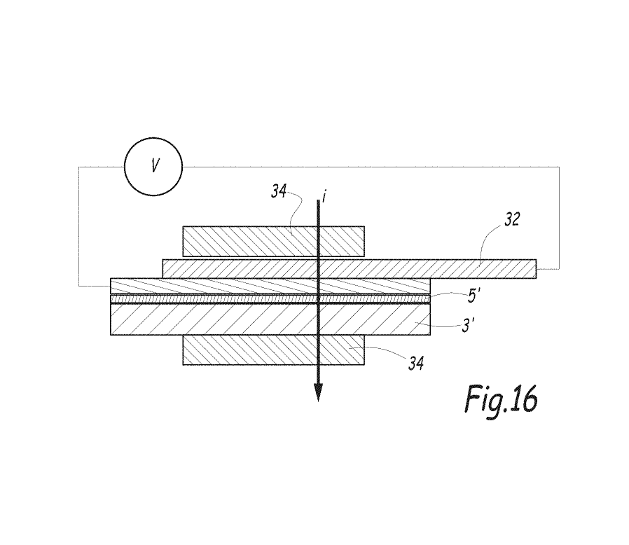

The inventors have in particular measured, for three different metal strip samples bearing a chromium-nitride based coating layer, the contact resistance (ICR) between the sample and a gas diffusion layer of the fuel cell using the assembly shown in FIG. 16.

Samples 1 and 2 are samples of strips 1′, obtained according to the above example of the method described above by cathode sputtering in a deposition chamber 20 comprising an upstream cover 29 and a downstream cover 28. Sample 3 is from a strip that is not according to the invention.

As illustrated in FIG. 16, the contact resistance is measured by gripping an assembly formed by a reference gas diffusion layer 32 and a sheet obtained by cutting from the strip to be tested between two copper plates 34, then applying a current with known intensity I to this assembly. The gas diffusion layer 32 used by the inventors is a reference 34BC layer marketed by SGL Group.

One then measures the difference in potential between the diffusion layer 32 and the surface of the sheet, and deduces the contact resistance therefrom between the sheet and the diffusion layer 32.

This method for measuring the contact resistance of a fuel cell bipolar plate is traditional and well known by those skilled in the art.

The inventors also experimentally determined the composition of the surface zone 8 of the coating layer.

Table 1 below reproduces the results of these experiments.

TABLE 1
Contact resistances measured for the tested samples

| | | | Measured contact |
|---|---|---|---|
| | | | resistance (ICR) |
| Sample | x1 | y1 | (mΩ · cm²) |
| 1 | 1.0 | 0.8 | 4.8 |
| 2 | 0.9 | 0.8 | 5.7 |
| 3 | 0.8 | 1.4 | 105 |

In this table, one can see the one obtains contact resistance values below 10 mΩ·cm² at 100 N·cm⁻² for coatings having surface zones in which the atomic oxygen content is, according to the invention, strictly lower than the atomic nitrogen content in the surface zone (samples 1 and 2). On the contrary, in the case of sample 3, where the atomic oxygen content is greater than or equal to the atomic nitrogen content in the surface zone of the coating, and which is therefore not a sample according to the invention, the contact resistance is greater than 100 mΩ·cm² at 100 N·cm⁻². It is therefore much higher than 10 mΩ·cm² at 100 N·cm⁻².

The inventors also measured, for samples 1 to 3, the composition of the interface zone 6 and the core zone 7. The results of these measurements are reproduced in table 2 below.

TABLE 2
Measured compositions of the core zones
and interface zones of the coating layers

| Sample | x2 | y2 | x3 | y3 |
|---|---|---|---|---|
| 1 | 0.9 | 0.4 | 1.3 | 0.4 |
| 2 | 1.1 | 0.3 | 1.0 | 0.3 |
| 3 | 0.8 | 0.8 | 0.77 | 0.44 |

As previously explained, the inventors of the present invention also discovered that the particular composition of the interface zone 6 of the coating layer 5′ according to the invention is advantageous. Indeed, the inventors observed that the appearance of the coating layer 5′ is particularly good when the atomic oxygen content of the interface zone 6 is strictly lower than its atomic nitrogen content. Thus, the risk of unsticking of the coating layer 5′ from the substrate 3′ during the deformation of the blank obtained from the strip 1 to form the plates 13, for example by stamping, is minimized. An effort is made to avoid such unsticking, since it risks compromising the integrity of the bipolar plate 11 or harming its electrical conductivity and may result in electrolytic poisoning.

Obtaining the advantageous atomic oxygen content of the surface zone 8 results from the presence of the first prohibited area 22, i.e., the limitation of the chromium nitride deposition downstream from the target 22 in the method for manufacturing the metal strip 1′ according to the above examples.

Obtaining the advantageous atomic oxygen content of the interface zone 6 results from the presence of the second prohibited area 23, i.e., the limitation of the chromium nitride deposition upstream from the target 22 in the method for manufacturing the metal strip 1′ according to an example.

In particular, measurements have shown that a chromium nitride deposition done on the stainless steel substrate in a deposition chamber 20 placed under vacuum and for which one has minimized the degassing rate before deposition, but while allowing the chromium nitride to be deposited along its natural trajectory, without limitation of the deposition area for example by covers, results in a coating layer having atomic oxygen contents significantly outside the ranges described above, in particular in the interface zone and the surface zone of the coating layer. In this case, the inventors have obtained a coating layer having a contact resistance (ICR) greater than 100 mΩ·cm² at 100 N·cm⁻² and further having lower adherence than when the deposition area is limited upstream from the deposition cathode.

Thus, a simple minimization of the presence of oxygen in the deposition chamber 20 using traditional techniques does not make it possible to obtain the coating layer 5′ as previously described.

According to one alternative, the invention relates to a metal sheet or blank obtained by cutting the metal strip 1′.

The metal sheet according to the invention can also be obtained using a method similar to that previously described to obtain the strip 1, but starting from a substrate 3′ in the form of a sheet, rather than a substrate 3′ in the form of a strip. Such a sheet has properties identical to those of the strip 1′.

The invention has been described for a coating layer 5, 5′ formed on a face of the substrate 3, 3′. Alternatively, the metal strip 1, 1′, as well as the plates 13 and the bipolar plates 11 manufactured from this strip 1, 1′, can comprise a coating layer 5, 5′ of the type previously defined on each of their faces.

Such a coating layer on both faces of the substrate 3; 3′ can be obtained in a single passage or several passages, for example two passages, in the deposition chamber 20.

1. A metal strip or sheet comprising a substrate made from stainless steel covered with at least one layer of a chromium-nitride based coating wherein the chromium-nitride based coating layer is textured.

2. The strip or sheet according to claim 1, wherein the coating layer has an epitaxial relationship with the substrate.

3. The strip or sheet according to claim 1, wherein the chromium-nitride based coating layer is obtained using a physical vapor deposition method.

4. The strip or sheet according claim 1, wherein the chromium-nitride based coating layer is formed directly on the stainless steel substrate without interposition of a passive layer.

5. The strip or sheet according to claim 1, wherein the substrate has a thickness comprised between 75 micrometers and 200 micrometers.

6. The strip or sheet according to claim 1, wherein the grains of the substrate have a size strictly smaller than 50 micrometers.

7. The strip or sheet according to claim 1, wherein the coating layer has a columnar structure.

8. The strip or sheet according to claim 1, wherein the coating layer optionally comprises oxygen, said coating layer being obtained by physical vapor deposition (PVD), characterized in that the coating layer has, on its surface, a surface zone comprising an atomic oxygen content strictly lower than its atomic nitrogen content.

9. The metal strip or sheet according to claim 8, wherein the surface zone has a height smaller than or equal to 15% of the total thickness of the coating layer.

10. The metal strip (1′) or sheet according to one of claims 8, wherein the coating layer comprises, at the interface with the substrate, an interface zone comprising an atomic oxygen content strictly lower than its atomic nitrogen content.

11. The metal strip or sheet according to claim 10, wherein the interface zone has a height less than or equal to 15% of the total thickness of the coating layer.

12. The metal strip or sheet according to claim 8, which consists, starting from the substrate and moving toward the surface of the coating layer, of the interface zone, a core zone and the surface zone, said zones being superimposed along a direction normal to the mean plane of the substrate.

13. A plate obtained by deforming a strip or sheet according to claim 1.

14. A bipolar plate for a fuel cell comprising at least one plate according to claim 13.

15. A method for manufacturing a metal strip or sheet, comprising the following steps:
providing a stainless steel substrate comprising, on its surface, a passive layer formed by natural oxidation of the stainless steel of the substrate;
completely stripping the passive layer in at least certain areas of the substrate; and
depositing chromium nitride on the areas of the substrate in which the passive layer has been stripped so as to form a chromium-nitride based coating layer directly on the stainless steel substrate without interposition of a passive layer the coating layer thus formed being textured.

16. The method according to claim 15, wherein the coating layer thus formed has an epitaxial relationship with the substrate.

17. The method according to claim 15, wherein the stripping is a physical stripping.

18. The method according to claim 15, wherein the chromium-nitride based coating layer is deposited using a physical vapor deposition method, in particular cathode sputtering.

19. The method according to claim 18, wherein the chromium nitride is deposited on the substrate in a deposition installation comprising a deposition chamber and a chromium target arranged in the deposition chamber the substrate traveling through the deposition chamber in a longitudinal direction, the deposition chamber comprising a deposition area with a length strictly smaller than the length of the deposition chamber considered along the longitudinal direction, and at least a first prohibited area, adjacent to the deposition area in the longitudinal direction, and during the deposition, the chromium nitride is deposited on the substrate only in the deposition area and no chromium nitride is deposited on the substrate in the first prohibited area.

20. The strip or sheet according to claim 3, wherein the chromium-nitride based coating layer is deposited by cathode sputtering.

21. The strip or sheet according to claim 7, wherein the width of the columns is comprised between 10% and 20% of the thickness of the coating layer.

22. The strip or sheet according to claim 5, wherein the substrate has a thickness smaller than or equal to 100 micrometers.

23. The strip or sheet according to claim 6, wherein the grains of the substrate have a size comprised between 10 micrometers and 30 micrometers.

24. The method according to claim 18, wherein the chromium-nitride based coating layer is deposited by cathode sputtering.
